(19) United States
(12) Patent Application Publication
(10) Pub. No.: US 2025/0309026 A1
(43) Pub. Date: Oct. 2, 2025

(54) SEMICONDUCTOR MODULE

(71) Applicant: JMJ Korea Co., Ltd., Busan (KR)

(72) Inventor: Yun Hwa CHOI, Busan (KR)

(73) Assignee: JMJ Korea Co., Ltd., Busan (KR)

(21) Appl. No.: 18/747,480

(22) Filed: Jun. 19, 2024

(30) Foreign Application Priority Data
Mar. 27, 2024 (KR) 10-2024-0041958

(51) Int. Cl. H01L 23/36; H01L 23/00; H01L 23/13; H01L 23/31; H01L 23/473; H01L 23/538; H01L 25/10

(52) U.S. Cl. CPC H01L 23/36; H01L 23/13; H01L 23/31; H01L 23/5383; H01L 24/32; H01L 25/105; H01L 23/473; H01L 2224/32225; H01L 2225/1011

(57) ABSTRACT

Provided is a semiconductor module including: a multilayer insulating substrate comprising at least two metal layers which are insulated from each other and an insertion groove to which at least one first semiconductor component is inserted, wherein one surface or the other surface of the at least one first semiconductor component is electrically connected to the metal layers by using a bonding layer interposed therebetween; an insulating material which surrounds at least two surfaces of the first semiconductor component in the insertion groove; radiation substrates which are electrically or structurally bonded to one surface or the other surface of the at least one first semiconductor component; and at least one second semiconductor component which is installed on an upper surface, a lower surface, or both upper and lower surfaces of the multilayer insulating substrate, wherein a depth of the insertion groove is greater than a depth of the first semiconductor component. Accordingly, high power may be controlled and heat generated by high power may be radiated.

### CROSS-REFERENCE TO RELATED PATENT APPLICATION

This application claims the benefit of Korean Patent Application No. 10-2024-0041958, filed on Mar. 27, 2024, in the Korean Intellectual Property Office, the disclosure of which is incorporated herein in its entirety by reference.

### BACKGROUND OF THE INVENTION

### Field of the Invention

The present invention relates to a semiconductor module, particularly, to a semiconductor module which may control high power and radiate heat generated by high power, and more particularly, to a semiconductor module in which a metal pattern combines a relatively thick multilayer insulating substrate with a radiation substrate so as to stably control high power and to efficiently radiate heat generated due to use of high power so that electrical and structural stability may be secured.

### Description of the Related Art

In general, a semiconductor package is used by being installed on a mother board or a printed circuit board after at least one semiconductor chip is installed on a lead frame or a printed circuit board and is sealed by using a sealing resin. Meanwhile, as electronic devices have been accelerated, increased in capacity, and highly integrated, power elements applied to electronic devices are required to be miniaturized, weight-lightened, and multifunctionalized. In this regard, a power module package in which a plurality of power semiconductor chips and control semiconductor chips is integrated on one semiconductor chip has been introduced.

For example, as illustrated in FIG. 1, a power module package according to a prior art has a structure where a first metal layer 11, a ceramic insulating layer 12, and a second metal layer 13 are stacked, wherein the second metal layer 13 is generally a relatively thick metal layer having a thickness of 0.1 mm through 1.5 mm so that high power may be applied thereto.

That is, a power semiconductor chip 14 is installed on the second metal layer 13 and a control semiconductor chip 16 which has a relatively smaller installation area than that of the power semiconductor chip 14 is installed on a third metal layer 15 that is separately formed from the second metal layer 13. However, as high temperature heat generated from the power semiconductor chip 14 needs to be efficiently radiated while the power module package is operated, heat radiation may not be efficiently performed due to the control semiconductor chip 16 which is closely disposed so that thermal stability or electrical stability may be hardly secured.

Accordingly, there is a demand for the development of a technology that may design a PCB substrate and a radiation substrate on which semiconductor components are installed so that high power may be applied through a metal pattern and heat radiation may be efficiently performed through an embedded semiconductor module structure.

### SUMMARY OF THE INVENTION

The present invention provides a semiconductor module in which a metal pattern combines a relatively thick multilayer insulating substrate with a radiation substrate so as to stably control high power and to efficiently radiate heat generated due to use of high power so that electrical and structural stability may be secured.

According to an aspect of the present invention, there is provided a semiconductor module including: a multilayer insulating substrate including at least two metal layers which are insulated from each other and an insertion groove to which at least one first semiconductor component is inserted, wherein one surface or the other surface of the at least one first semiconductor component is electrically connected to the metal layers by using a bonding layer interposed therebetween; an insulating material which surrounds at least two surfaces of the first semiconductor component in the insertion groove; radiation substrates which are electrically or structurally bonded to one surface or the other surface of the at least one first semiconductor component; and at least one second semiconductor component which is installed on an upper surface, a lower surface, or both upper and lower surfaces of the multilayer insulating substrate, wherein a depth of the insertion groove is greater than a depth of the first semiconductor component.

Here, the depth of the insertion groove may be above 20 μm and the thickness of the metal layer may be above 0.1 mm.

Also, the metal layer of the multilayer insulating substrate may be formed of Cu or a metal material containing 50% or more of Cu.

Also, the multilayer insulating substrate may be a printed circuit board (PCB).

Also, the radiation substrate may include at least one insulating layer.

Also, the insulating layer may be formed of Al₂O₃, AlN, Si₃N₄, ZTA.

Here, the heat conductivity of the insulating layer may be 2 W/mK through 30 W/mK.

Also, the radiation substrate may further include radiation fins to increase radiation efficiency by using air or cooling water.

Here, the radiation fins may be bonded to one surface of the radiation substrate by using a conductive adhesive or a non-conductive adhesive or by ultrasonic bonding.

In addition, the semiconductor module may further include a water jacket structurally bonded to the radiation substrate to flow cooling water to the radiation fins.

Also, the first semiconductor component may be a power semiconductor chip or a compound semiconductor chip including a MOSFET, an IGBT, or a diode.

Also, the insulating material which surrounds the first semiconductor component may be a liquid insulating material containing an epoxy component which is hardened at 50° C. or above.

Also, the insulating material which surrounds the first semiconductor component may contain a silicon component.

Also, the radiation substrate may include an upper metal layer and the upper metal layer may include a metal convex part on the surface thereof to be bonded to one surface or the other surface of the first semiconductor component.

Also, the bonding layer used to bond the multilayer insulating substrate and one surface or the other surface of the first semiconductor component may contain Ag, Cu, or 50% or more of Ag and Cu.

Also, the at least one first semiconductor component may be bonded to the multilayer insulating substrate or the radiation substrate by sintering or soldering.

Also, the at least one second semiconductor component may be installed on the upper surface, the lower surface, or both upper and lower surfaces of the multilayer insulating substrate by using a bonding layer containing Ag, Cu, or 50% or more of Ag and Cu.

Also, one or more metal layers of the multilayer insulating substrate may be electrically connected to a drain terminal of the first semiconductor component.

Also, one or more metal layers of the multilayer insulating substrate may include a drawn metal layer exposed by being extended to the inside of the insertion groove.

Here, the drawn metal layer may be bonded to the radiation substrate by using a conductive or non-conductive adhesive or may be directly bonded to the radiation substrate by using ultrasonic waves.

Also, the at least one second semiconductor component may be a gate drive IC which operates a gate of the first semiconductor component.

Here, the at least one second semiconductor component may be installed on the upper surface, the lower surface, or both upper and lower surfaces of the multilayer insulating substrate by using a solder containing Sn.

Also, the thickness of the metal layer in the multilayer insulating substrate which is electrically connected to one surface or the other surface of the first semiconductor component may be greater than the thickness of the metal layer in the multilayer insulating substrate which is electrically connected to the second semiconductor component.

Also, a metal post may be bonded between one surface or the other surface of the at least one first semiconductor component and the facing surface of the radiation substrate.

Also, the first semiconductor component may include a package structure including a semiconductor chip, at least two electrical terminals, and an insulation resin and the electrical terminals may be partially or entirely exposed to the upper surface or the lower surface of the package.

Here, the first semiconductor component may be manufactured by using transfer molding.

Also, the multilayer insulating substrate may further include an insulating layer and the radiation substrate may be electrically or structurally bonded to the metal layer of the multilayer insulating substrate, the insulating layer, or both insulating layer and metal layer.

Also, the radiation substrate may be partially inserted and bonded to the multilayer insulating substrate.

Meanwhile, the semiconductor module may be used in a power conversion device in an inverter or a converter.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a semiconductor module according to a prior art;

FIG. 2 illustrates a first example of a semiconductor module according to an embodiment of the present invention;

FIGS. 3A and 3B illustrate second examples of a semiconductor module according to an embodiment of the present invention;

FIG. 4 illustrates a third example of a semiconductor module according to an embodiment of the present invention;

FIG. 5 separately illustrates a first semiconductor component in the third example of FIG. 4;

FIG. 6 illustrates a fourth example of a semiconductor module according to an embodiment of the present invention; and

FIG. 7 separately illustrates a layout structure of a first semiconductor component in the fourth example of FIG. 6.

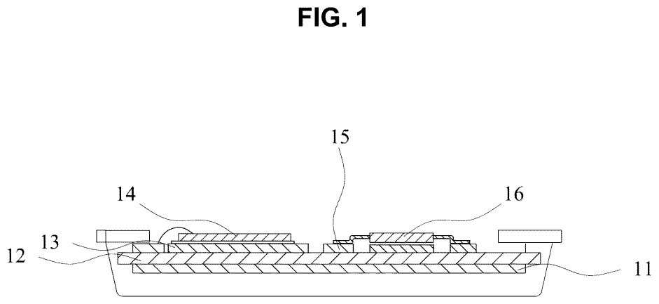

### DETAILED DESCRIPTION OF THE INVENTION

Hereinafter, embodiments of the present invention will be described in more detail with reference to the accompanying drawings.

A semiconductor module according to an embodiment of the present invention includes a multilayer insulating substrate 110 including at least two metal layers 111 which are insulated from each other and an insertion groove 112 to which at least one first semiconductor component 120 is inserted, an insulating material 130, radiation substrates 140A and 140B, and at least one second semiconductor component 150, wherein in the multilayer insulating substrate 110, one surface or the other surface of the at least one first semiconductor component 120 is electrically connected to the metal layers 111 by using a bonding layer 113 interposed therebetween, the insulating material 130 surrounds at least two surfaces of the first semiconductor component 120 in the insertion groove 112, the radiation substrates 140A and 140B are electrically or structurally bonded to one surface or the other surface of the at least one first semiconductor component 120, and the at least one second semiconductor component 150 is installed on an upper surface, a lower surface, or both upper and lower surfaces of the multilayer insulating substrate 110. Here, a depth D of the insertion groove 112 is greater than a thickness T of the first semiconductor component 120 so that high power may be controlled and heat generated by high power may be radiated.

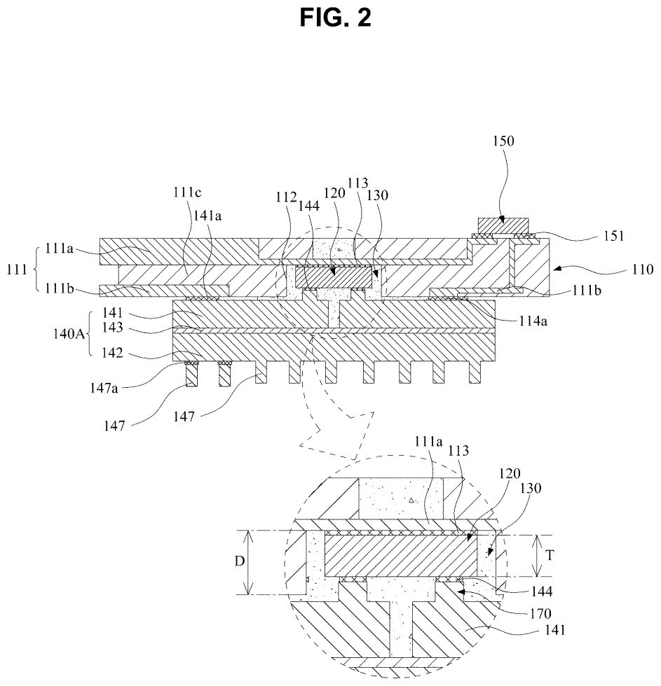

Hereinafter, the semiconductor module described above will be described in more detail with reference to FIGS. 2 through 7.

First, referring to FIGS. 2, 3A, 3B, 4, and 6, the multilayer insulating substrate 110 is formed of the at least two metal layers 111 including an upper metal layer 111a and a lower metal layer 111b which are insulated from each other, an insulating layer 111c which insulates the at least two metal layers 111, and the insertion groove 112 to which the at least one first semiconductor component 120 is inserted. Also, one surface or the other surface of the at least one first semiconductor component 120 is electrically connected to the surface of any one of the metal layers 111 by using the bonding layer 113 interposed therebetween so that an electrical signal may be applied thereto.

Here, a thickness of the metal layers 111 may be at least 0.2 mm so that a thickness T of each of the metal layers 111a and 111b is above 0.1 mm. Accordingly, the first semiconductor component 120 or the second semiconductor component 150 may stably control high power and each of the metal layers 111a and 111b may be electrically bonded to at least two terminals of the first semiconductor component 120 or the second semiconductor component 150, wherein the terminals may be a source terminal, a gate terminal, and/or a drain terminal.

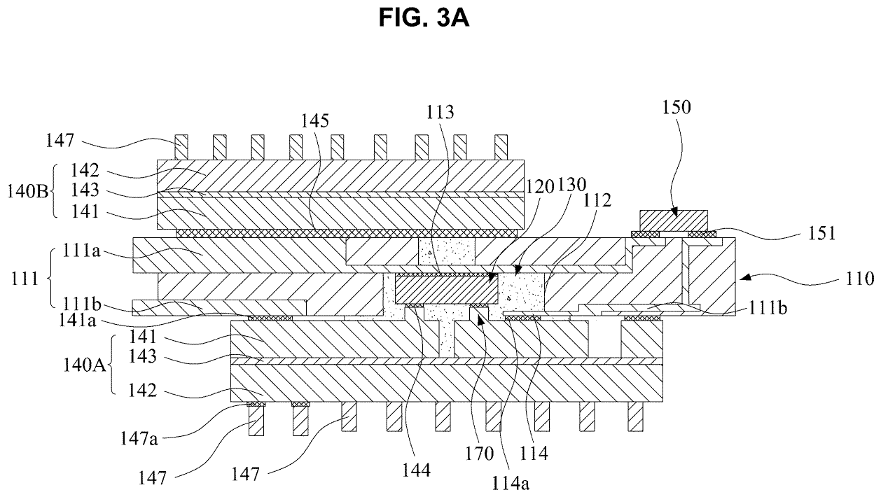

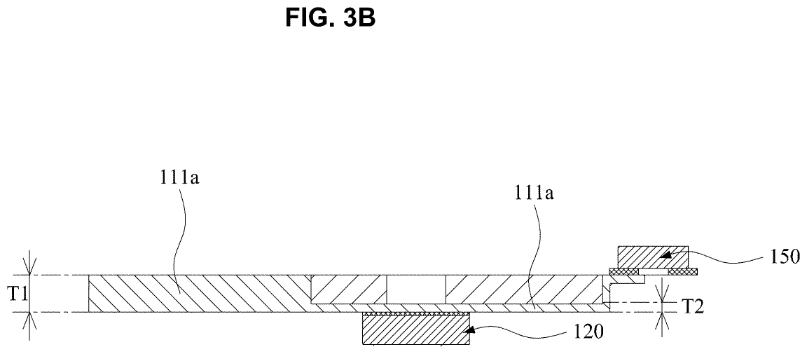

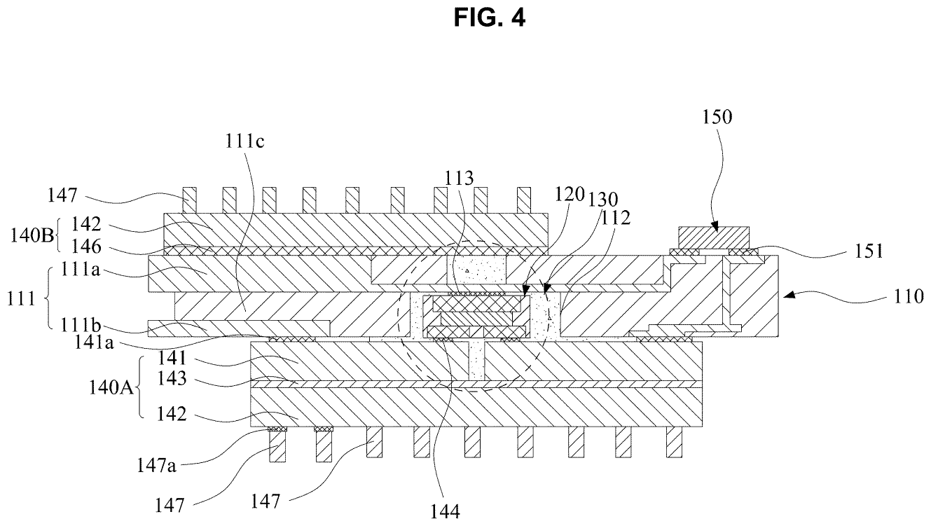

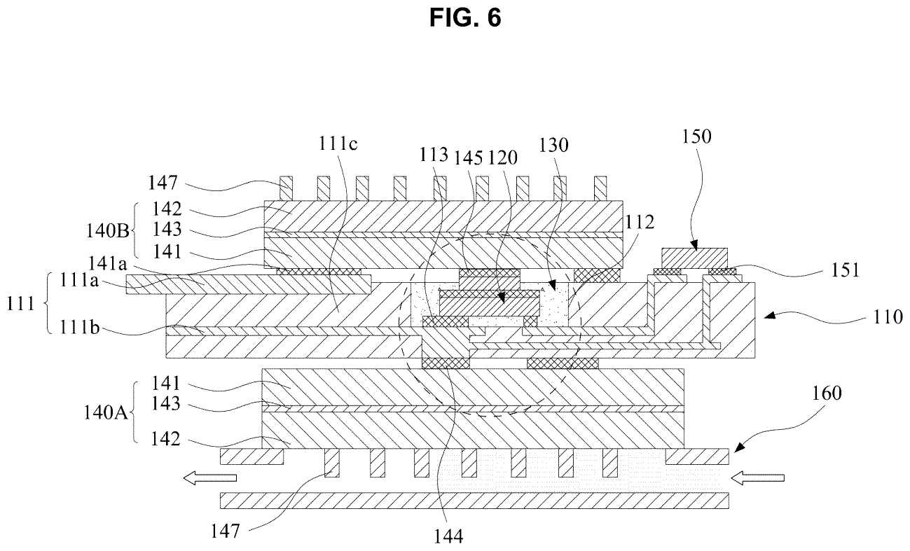

That is, as illustrated in an enlarged view of FIG. 2, the depth D of the insertion groove 112 in the multilayer insulating substrate 110 is formed to be greater than the thickness T of the first semiconductor component 120 so that the semiconductor module may have an embedded-form structure. In this regard, the depth D of the insertion groove 112 may be preferably above 20 μm and a thickness of each of the metal layers 111 may be preferably above 0.1 mm. The depth D of the insertion groove 112 and the thicknesses of the metal layers 111 in the first example of FIG. 2 may be applied as in the same manner as in a second example of FIGS. 3A and 3B, a third example of FIG. 4, and a fourth example of FIG. 6.

Also, the first semiconductor component 120 may be a power semiconductor chip or a compound semiconductor chip including a MOSFET, an IGBT, or a diode and the insulating material 130 that surrounds the first semiconductor component 120 may be a liquid insulating material 130 containing an epoxy component. Here, the liquid insulating material 130 is hardened at 50° C. or above through a hardening process and stably insulates the semiconductor component 120 so that air insulation breakdown may be prevented and insulation reliability may be secured.

Here, the insulating material 130 that surrounds the first semiconductor component 120 contains a silicon component to secure excellent insulation or contain a thermal conductive silicon component to secure excellent insulation and thermal conductivity.

Also, the metal layers 111 in the multilayer insulating substrate 110 may be Cu or metal materials containing 50% or more of Cu and thereby, excellent electrical conductivity and thermal conductivity may be provided. The multilayer insulating substrate 110 may be a printed circuit board (PCB).

In addition, as illustrated in the first example of FIG. 2, the one or more metal layers 111a and 111b of the multilayer insulating substrate 110 may be electrically connected to a source terminal and a drain terminal of the first semiconductor component 120 that supplies high power.

Moreover, the bonding layer 113 used to bond the multilayer insulating substrate 110 to one surface or the other surface of the first semiconductor component 120 may contain Ag, Cu, or 50% or more Ag and Cu and thereby, electrical conductivity and thermal conductivity may be improved.

Meanwhile, as illustrated in the second example of FIGS. 3A and 3B, one or more metal layers 111 in the multilayer insulating substrate 110 include a drawn metal layer 114 exposed by being extended to the inside of the insertion groove 112, wherein the drawn metal layer 114 may be bonded to the upper metal layer 141 of the radiation substrate 140A and thereby, may be connected to the first semiconductor component 120.

For example, the drawn metal layer 114 may be bonded to the upper metal layer 141 of the radiation substrates 140A and 140B by using a conductive or non-conductive adhesive 114a so as to be electrically or structurally connected or may be directly bonded to the upper metal layer 141 of the radiation substrates 140A and 140B by using ultrasonic waves.

That is, as illustrated in the first example of FIG. 2, the adhesive 114a is applied to the lower metal layer 111b electrically connected to the second semiconductor component 150 or the upper metal layer 141 of the radiation substrate 140A in advance so as to be bonded to each other. Also, as illustrated in the second example of FIGS. 3A and 3B, the lower metal layer 111b electrically connected to the second semiconductor component 150 and the upper metal layer 141 of the radiation substrate 140A are closely adhered to each other. Then, the adhesive 114a may be applied or ultrasonic waves may be used to bond the lower metal layer 111b and the upper metal layer 141.

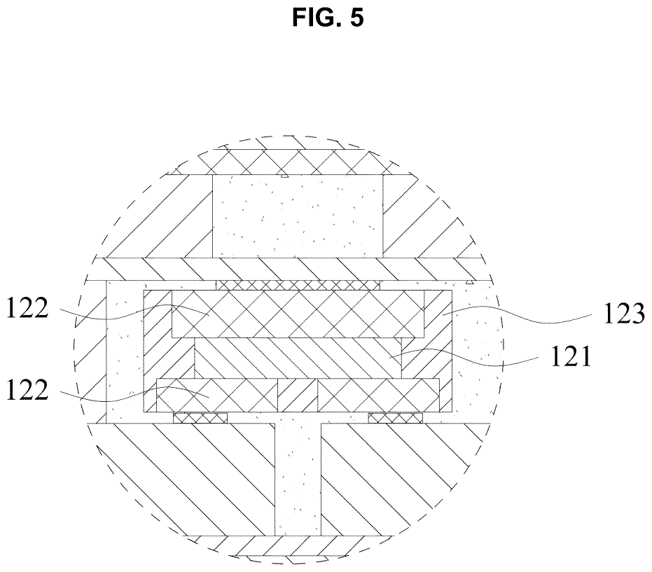

Also, as in the third example of FIGS. 4 and 5, the first semiconductor component 120 may have a package structure including a semiconductor chip 121, at least two electrical terminals 122, and an insulation resin 123. Here, the electrical terminals 122 may be partially or entirely exposed to the upper surface or the lower surface of the package so that heat generated from the first semiconductor component 120 may be radiated through the electrical terminals 122.

Here, the first semiconductor component 120 may be compressed with the insulation resin 123 by a transfer molding method.

Next, referring to FIGS. 2, 3A, 3B, 4, and 6, the insulating material 130 surrounds at least two surfaces of the first semiconductor component 120 within the insertion groove 112 and thereby, electrically insulates the first semiconductor component 120.

Next, referring to FIGS. 2, 3A, 3B, 4, and 6, the radiation substrates 140A and 140B are bonded to one surface or the other surface of the at least one first semiconductor component 120. Here, bonding layers 141a are disposed on the metal layers 111 of the multilayer insulating substrate 110, the insulating layer 111c, or both metal layers 111 and the insulating layer 111c to bond the radiation substrates 140A and 140B and the first semiconductor component 120 and thereby, heat generated during operating of the first semiconductor component 120 may be efficiently radiated to the outside so that electrical stability may be secured.

More specifically, as in the first example of FIG. 2, the radiation substrates 140A and 140B may include the lower radiation substrate 140A bonded to one surface of the first semiconductor component 120 by using a bonding layer 144 interposed therebetween and as in the second example of FIGS. 3A and 3B, the third example of FIG. 4, and the fourth example of FIG. 6, the radiation substrates 140A and 140B may include the lower radiation substrate 140A bonded to one surface of the first semiconductor component 120 by using the bonding layer 144 interposed therebetween and the upper radiation substrate 140B bonded to the other surface of the first semiconductor component 120 and/or the multilayer insulating substrate 110 by using a bonding layer 145 interposed therebetween.

Also, as in the first example of FIG. 2, the second example of FIGS. 3A and 3B, and the fourth example of FIG. 6, the lower radiation substrate 140A or the upper radiation substrate 140B may be an insulating substrate including an upper metal layer 141, a lower metal layer 142, and an insulating layer 143 interposed between the upper metal layer 141 and the lower metal layer 142, wherein the upper metal layer 141 and the lower metal layer 142 are structurally connected to one surface or the other surface of the first semiconductor component 120.

In addition, as in the third example of FIG. 4, the lower radiation substrate 140A may be an insulating substrate including the upper metal layer 141, the lower metal layer 142, and the insulating layer 143 interposed between the upper metal layer 141 and the lower metal layer 142, wherein the upper metal layer 141 and the lower metal layer 142 are structurally connected to one surface of the first semiconductor component 120. The upper radiation substrate 140B may be a metal substrate including the lower metal layer 142 structurally connected to the other surface of the first semiconductor component 120 by using an insulating bonding layer 146 interposed therebetween.

That is, one or more radiation substrates 140A and 140B may be electrically or structurally bonded to the metal layers 111a and 111b, the insulating layer 111c, or both insulating layer 111c and metal layers 111a and 111b, wherein the metal layers 111a and 111b and the insulating layer 111c are included in the multilayer insulating substrate 110.

Although not illustrated, one or more radiation substrates 140A and 140B may be partially inserted and bonded to the multilayer insulating substrate 110. Here, the radiation substrates 140A and 140B may be adhered and bonded to the multilayer insulating substrate 110 or may be partially inserted into an engraved groove formed on the multilayer insulating substrate 110 so as to be bonded to each other so that structural stability may be improved.

Moreover, the radiation substrates 140A and 140B may have an insulating substrate structure including at least one insulating layer 143, wherein the insulating layer 143 may be formed of Al₂O₃, AlN, Si₃N₄, or Zirconia Toughened Alumina (ZTA) having excellent heat conductivity and wear resistance.

More specifically, heat conductivity of the insulating layer 143 may be preferably 2 W/mK through 30 W/mK.

Also, referring to FIGS. 2, 3A, 3B, 4, and 6, the radiation substrates 140A and 140B may include protruded radiation fins 147 having various forms and structures such as a cylinder or a polygonal column to increase radiation efficiency by an air cooling method or a water cooling method using air, refrigerant gas, coolant fluid, or cooling water. Accordingly, a radiation area may be expanded and thereby, radiation efficiency may be increased.

Here, the radiation fins 147 may be bonded to one surface of the radiation substrates 140A and 140B by using a metal or non-metal adhesive 147a or by ultrasonic bonding and may be protruded.

For example, the radiation fins 147 may be formed as in one body with the lower metal layer 142 of the radiation substrates 140A and 140B, may be bonded to the radiation substrates 140A and 140B by using a metal adhesive or a non-metal adhesive 147a, or may be bonded to the radiation substrates 140A and 140B by using ultrasonic waves, instead of an adhesive.

Also, as illustrated in FIG. 6, a water jacket 160 including a flow path may be further included, wherein the water jacket 160 is structurally bonded to the radiation substrates 140A and 140B for refrigerant gas, coolant fluid, or cooling water to flow to the radiation fins 147 and the flow path includes an inlet, an outlet, and the radiation fins 147 exposed to contact refrigerant gas or cooling water. Accordingly, radiation efficiency may be increased and thereby, electrical stability may be improved.

In addition, as illustrated in the first example and the second example of FIGS. 2, 3A and 3B, a metal convex part 170 is protruded and formed to bond one surface or the other surface of the first semiconductor component 120 to a part of the surface of the upper metal layer 141 of the radiation substrates 140A and 140B by using the bonding layer 144 interposed therebetween. In this regard, bonding accuracy of the first semiconductor component 120 may be increased and bonding reliability may be increased compared with bonding of the first semiconductor component 120 to the flat upper metal layer 141.

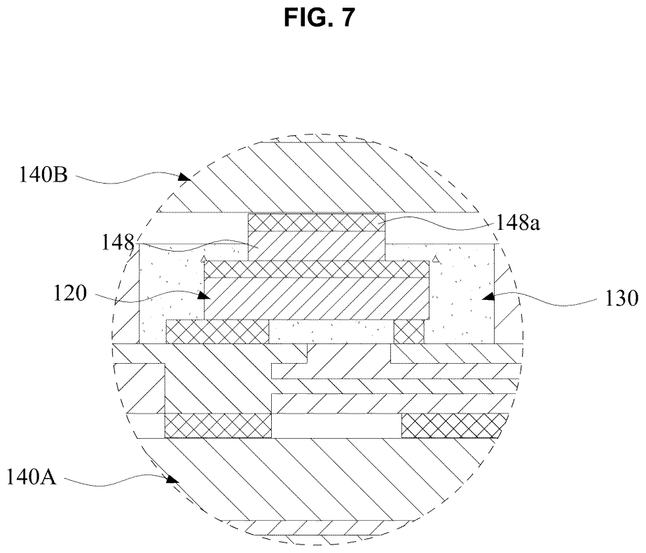

Also, as in the fourth example of FIGS. 6 and 7, a bonding layer 148a may be interposed between one surface or the other surface of the at least one first semiconductor component 120 and the facing surface of the radiation substrates 140A and 140B and thereby, a metal post 148 may be electrically or structurally bonded therebetween so that heat conductivity may be increased and thereby, radiation efficiency may be improved.

Next, referring to FIGS. 2, 3A, 3B, 4, and 6, one or more second semiconductor components 150 are included and installed on the upper surface, the lower surface, or both upper and lower surfaces of the multilayer insulating substrate 110.

Here, one or more second semiconductor components 150 may be a gate drive IC which operates a gate of the first semiconductor component 120 and may be installed on the multilayer insulating substrate 110 by using a solder containing Sn.

Meanwhile, referring to FIG. 3B, the thickness T1 of the metal layer 111 in the multilayer insulating substrate 110 which is electrically connected to one surface or the other surface of the first semiconductor component 120, for example, the upper metal layer 111a, is greater than the thickness T2 of the metal layer 111 which is electrically connected to the second semiconductor component 150, for example, the upper metal layer 111a. Accordingly, the metal layers 111 may be designed differently according to intensity of power applied to each of the semiconductor components 120 and 150. In this regard, the weight may be minimized and lightened, the cost of production may be reduced, and products may be compact.

Meanwhile, at least one first semiconductor component 120 may be bonded to the multilayer insulating substrate 110 or the radiation substrates 140A and 140B by sintering or soldering. Referring to FIGS. 2, 3A, 3B, 4, and 6, a bonding layer 151 used to bond one surface or the other surface of the second semiconductor component 150 may contain Ag, Cu, or 50% or more of Ag and Cu and thus, electrical conductivity and heat conductivity may be increased.

Also, the semiconductor module described in each example may be used in a power conversion device of an inverter or a converter. For example, the power conversion device may be included in an inverter, a converter, or an on board charger (OBC) that operates a three-phase motor, converts, or controls power. Here, excessive heat is generated while power is converted into another power such as a specific current, a specific voltage, or a specific frequency. Accordingly, cooling may be efficiently performed through the radiation substrate 140 according to an embodiment of the present invention.

According to the embedded-form semiconductor module structure described above and the characteristic thereof that is applied to a power conversion device, the metal pattern combines the relatively thick multilayer insulating substrate with the radiation substrate so as to stably control high power and to efficiently radiate heat generated due to use of high power. Therefore, electrical and structural stability may be secured.

According to the present invention, due to the characteristic that is applied to a power conversion device, the metal pattern combines the relatively thick multilayer insulating substrate with the radiation substrate so as to stably control high power and to efficiently radiate heat generated due to use of high power. Therefore, electrical and structural stability may be secured.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor module comprising:
a multilayer insulating substrate comprising at least two metal layers which are insulated from each other and an insertion groove to which at least one first semiconductor component is inserted, wherein one surface or the other surface of the at least one first semiconductor component is electrically connected to the metal layers by using a bonding layer interposed therebetween;
an insulating material which surrounds at least two surfaces of the first semiconductor component in the insertion groove;
radiation substrates which are electrically or structurally bonded to one surface or the other surface of the at least one first semiconductor component; and
at least one second semiconductor component which is installed on an upper surface, a lower surface, or both upper and lower surfaces of the multilayer insulating substrate,
wherein a depth of the insertion groove is greater than a depth of the first semiconductor component.

2. The semiconductor module of claim 1, wherein the depth of the insertion groove is above 20 μm and the thickness of the metal layer is above 0.1 mm.

3. The semiconductor module of claim 1, wherein the metal layer of the multilayer insulating substrate is formed of Cu or a metal material containing 50% or more of Cu.

4. The semiconductor module of claim 1, wherein the radiation substrate comprises at least one insulating layer.

5. The semiconductor module of claim 1, wherein the radiation substrate further comprises radiation fins to increase radiation efficiency by using air or cooling water.

6. The semiconductor module of claim 5, wherein the radiation fins are bonded to one surface of the radiation substrate by using a conductive adhesive or a non-conductive adhesive or by ultrasonic bonding.

7. The semiconductor module of claim 5, further comprising a water jacket structurally bonded to the radiation substrate to flow cooling water to the radiation fins.

8. The semiconductor module of claim 1, wherein the insulating material which surrounds the first semiconductor component contains a silicon component or is a liquid insulating material containing an epoxy component which is hardened at 50° C. or above.

9. The semiconductor module of claim 1, wherein the radiation substrate comprises an upper metal layer and the upper metal layer comprises a metal convex part on the surface thereof to be bonded to one surface or the other surface of the first semiconductor component.

10. The semiconductor module of claim 1, wherein the bonding layer used to bond the multilayer insulating substrate and one surface or the other surface of the first semiconductor component contains Ag, Cu, or 50% or more of Ag and Cu.

11. The semiconductor module of claim 1, wherein the at least one first semiconductor component is bonded to the multilayer insulating substrate or the radiation substrate by sintering or soldering.

12. The semiconductor module of claim 1, wherein one or more metal layers of the multilayer insulating substrate comprise a drawn metal layer exposed by being extended to the inside of the insertion groove.

13. The semiconductor module of claim 12, wherein the drawn metal layer is bonded to the radiation substrate by using a conductive or non-conductive adhesive or is directly bonded to the radiation substrate by using ultrasonic waves.

14. The semiconductor module of claim 1, wherein the at least one second semiconductor component is a gate drive IC which operates a gate of the first semiconductor component.

15. The semiconductor module of claim 14, wherein the at least one second semiconductor component is installed on the upper surface, the lower surface, or both upper and lower surfaces of the multilayer insulating substrate by using a solder containing Sn.

16. The semiconductor module of claim 1, wherein the thickness of the metal layer in the multilayer insulating substrate which is electrically connected to one surface or the other surface of the first semiconductor component is greater than the thickness of the metal layer in the multilayer insulating substrate which is electrically connected to the second semiconductor component.

17. The semiconductor module of claim 1, wherein a metal post is bonded between one surface or the other surface of the at least one first semiconductor component and the facing surface of the radiation substrate.

18. The semiconductor module of claim 1, wherein the first semiconductor component comprises a package structure comprising a semiconductor chip, at least two electrical terminals, and an insulation resin and the electrical terminals are partially or entirely exposed to the upper surface or the lower surface of the package.

19. The semiconductor module of claim 1, wherein the multilayer insulating substrate further comprises an insulating layer and the radiation substrate is electrically or structurally bonded to the metal layer of the multilayer insulating substrate, the insulating layer, or both insulating layer and metal layer.

20. The semiconductor module of claim 1, wherein the radiation substrate is partially inserted and bonded to the multilayer insulating substrate.
